(19) United States
(12) Patent Application Publication
(10) Pub. No.: US 2010/0289036 A1
(43) Pub. Date: Nov. 18, 2010

(54) III-NITRIDE SEMICONDUCTOR LIGHT EMITTING DEVICE AND METHOD FOR MANUFACTURING THE SAME

(75) Inventors: Chang Tae Kim, Gyeonggi-do (KR); Tae Hee Lee, Chungcheongnam-do (KR)

Correspondence Address: HUSCH BLACKWELL LLP, 190 Carondelet Plaza, Suite 600, ST. LOUIS, MO, 63105, US

(73) Assignee: EPIVALLEY CO., LTD., Gyungbuk (KR)

(21) Appl. No.: 12/811,247

(22) PCT Filed: Dec. 31, 2008
(86) PCT No.: PCT/KR2008/007885

§ 371 Date: Jun. 30, 2010

(30) Foreign Application Priority Data
Dec. 31, 2007 (KR) 10-2007-0142025

(51) Int. Cl. H01L 33/02; H01L 33/00; H01L 33/30

(52) U.S. Cl. 257/87; 438/33; 257/103; 438/46; 257/E33.023; 257/E33.005

(57) ABSTRACT

The present invention provides a Ill-nitride semiconductor light emitting device and a method for manufacturing the same including: a substrate; a plurality of Ill-nitride semiconductor layers formed on the substrate, and provided with an active layer generating light by recombination of electrons and holes; a boundary surface defined between the substrate and the plurality of Ill-nitride semiconductor layers; and a pair of slant surfaces formed from the boundary surface on the substrate and the plurality of Ill-nitride semiconductor layers so as to emit light generated in the active layer to the outside.

### TECHNICAL FIELD

The present invention relates to a III-nitride semiconductor light emitting device and a method for manufacturing the same, and more particularly, to a III-nitride semiconductor light emitting device which can improve external quantum efficiency, and a method for manufacturing the same. The III-nitride semiconductor light emitting device means a light emitting device such as a light emitting diode including a compound semiconductor layer composed of Al₍ₓ₎Ga_{(y)}In_{(1-x-y)}N (0≦x≦1, 0≦y≦1, 0≦x+y≦1), and may further include a material composed of other group elements, such as SiC, SiN, SiCN and CN, and a semiconductor layer made of such materials.

### BACKGROUND ART

FIG. 1 is a view illustrating one example of a conventional III-nitride semiconductor light emitting device. The III-nitride semiconductor light emitting device includes a substrate 100, a buffer layer 200 grown on the substrate 100, an n-type III-nitride semiconductor layer 300 grown on the buffer layer 200, an active layer 400 grown on the n-type III-nitride semiconductor layer 300, a p-type III-nitride semiconductor layer 500 grown on the active layer 400, a p-side electrode 600 formed on the p-type III-nitride semiconductor layer 500, a p-side bonding pad 700 formed on the p-side electrode 600, an n-side electrode 800 formed on the n-type III-nitride semiconductor layer 300 exposed by mesa-etching the p-type III-nitride semiconductor layer 500 and the active layer 400, and a protective film 900.

In the case of the substrate 100, a GaN substrate can be used as a homo-substrate, and a sapphire substrate, a SiC substrate or a Si substrate can be used as a hetero-substrate. However, any type of substrate that can grow a nitride semiconductor layer thereon can be employed. In the case that the SiC substrate is used, the n-side electrode 800 can be formed on the side of the SiC substrate.

The nitride semiconductor layers epitaxially grown on the substrate 100 are grown usually by metal organic chemical vapor deposition (MOCVD).

The buffer layer 200 serves to overcome differences in lattice constant and thermal expansion coefficient between the hetero-substrate 100 and the nitride semiconductor layers. U.S. Pat. No. 5,122,845 discloses a technique of growing an AlN buffer layer with a thickness of 100 to 500 Å on a sapphire substrate at 380 to 800° C. In addition, U.S. Pat. No. 5,290,393 discloses a technique of growing an Al₍ₓ₎Ga₍₁₋ₓ₎N (0≦x<1) buffer layer with a thickness of 10 to 5000 Å on a sapphire substrate at 200 to 900° C. Moreover, U.S. Pub. No. 2006-0154454 discloses a technique of growing a SiC buffer layer (seed layer) at 600 to 990° C., and growing an In₍ₓ₎Ga₍₁₋ₓ₎N (0<x≦1) thereon. Preferably, an undoped GaN layer is grown prior to the n-type III-nitride semiconductor layer 300. The undoped GaN layer can be considered as a part of the buffer layer 200, or a part of the n-type III-nitride semiconductor layer 300.

In the n-type III-nitride semiconductor layer 300, at least the n-side electrode 800 formed region (n-type contact layer) is doped with a dopant. Preferably, the n-type contact layer is made of GaN and doped with Si. U.S. Pat. No. 5,733,796 discloses a technique of doping an n-type contact layer at a target doping concentration by adjusting the mixture ratio of Si and other source materials.

The active layer 400 generates light quanta (light) by recombination of electrons and holes. Normally, the active layer 400 contains In₍ₓ₎Ga₍₁₋ₓ₎N (0<x≦1) and has single or multi-quantum well layers.

The p-type III-nitride semiconductor layer 500 is doped with an appropriate dopant such as Mg, and has p-type conductivity by an activation process. U.S. Pat. No. 5,247,533 discloses a technique of activating a p-type III-nitride semiconductor layer by electron beam irradiation. Moreover, U.S. Pat. No. 5,306,662 discloses a technique of activating a p-type III-nitride semiconductor layer by annealing over 400° C. U.S. Pub. No. 2006-0157714 discloses a technique of endowing a p-type III-nitride semiconductor layer with p-type conductivity without an activation process, by using ammonia and a hydrazine-based source material together as a nitrogen precursor for growing the p-type III-nitride semiconductor layer.

The p-side electrode 600 is provided to facilitate current supply to the p-type III-nitride semiconductor layer 500. U.S. Pat. No. 5,563,422 discloses a technique associated with a light transmitting electrode composed of Ni and Au and formed almost on the entire surface of the p-type III-nitride semiconductor layer 500 and in ohmic-contact with the p-type III-nitride semiconductor layer 500. In addition, U.S. Pat. No. 6,515,306 discloses a technique of forming an n-type superlattice layer on a p-type III-nitride semiconductor layer, and forming a light transmitting electrode made of ITO thereon.

Meanwhile, the light transmitting electrode 600 can be formed thick not to transmit but to reflect light toward the substrate 100. This technique is called a flip chip technique. U.S. Pat. No. 6,194,743 discloses a technique associated with an electrode structure including an Ag layer with a thickness over 20 nm, a diffusion barrier layer covering the Ag layer, and a bonding layer containing Au and Al, and covering the diffusion barrier layer.

The p-side bonding pad 700 and the n-side electrode 800 are provided for current supply and external wire bonding. U.S. Pat. No. 5,563,422 discloses a technique of forming an n-side electrode with Ti and Al.

The protection film 900 can be made of SiO₂, and may be omitted.

In the meantime, the n-type III-nitride semiconductor layer 300 or the p-type III-nitride semiconductor layer 500 can be constructed as single or plural layers. Recently, a technology for making a vertical light emitting device by separating the III-nitride semiconductor layers from the substrate 100 by means of a laser or a wet etching has been introduced.

FIG. 2 is a view illustrating one example of a light reflection path 203 in a semiconductor layer of a light emitting device disclosed in U.S. Pub No. 2006-0192247. Light generated in the active layer cannot be discharged to the outside of the light emitting device due to total reflection caused by density difference between the semiconductor layer 202 and the outside of the light emitting device.

Such a phenomenon results in low external quantum efficiency of the light emitting device. FIG. 3 is a view illustrating one example of a light emitting device disclosed in Japan Patent 2836687. A curved surface is formed on one surface of the semiconductor layer, so that the light emitting device can improve external quantum efficiency.

FIG. 4 is a view illustrating one example of a light emitting device disclosed in U.S. Pub. No. 2006-0192247. A slant surface is formed on a side surface of the semiconductor layer to extract light, so that the light emitting device can improve external quantum efficiency.

However, the aforementioned light emitting devices have a disadvantage in that, since extraction of light generated in an active layer is limited to the semiconductor layer, light incident on the substrate is reflected as in the semiconductor layer and thus is not extracted.

### DISCLOSURE

### Technical Problem

Accordingly, the present invention has been made to solve the above-described shortcomings occurring in the prior art, and an object of the present invention is to provide a III-nitride semiconductor light emitting device which can improve external quantum efficiency, and a method for manufacturing the same.

Another object of the present invention is to provide a III-nitride semiconductor light emitting device having a slant surface on a side surface thereof to easily extract light, and a method for manufacturing the same.

Yet, another object of the present invention is to provide a III-nitride semiconductor light emitting device having a slant surface on a substrate thereof to easily extract light, and a method for manufacturing the same.

### Technical Solution

According to an aspect of the present invention, there is provided a III-nitride semiconductor light emitting device, including: a substrate; a plurality of III-nitride semiconductor layers formed on the substrate, and provided with an active layer generating light by recombination of electrons and holes; a boundary surface defined between the substrate and the plurality of III-nitride semiconductor layers; and a pair of slant surfaces formed from the boundary surface on the substrate and the plurality of III-nitride semiconductor layers so as to emit light generated in the active layer to the outside.

Also, according to another aspect of the present invention, the substrate comprises a broken surface below the substrate-side slant surface.

Also, according to another aspect of the present invention, the substrate is a sapphire substrate.

Also, according to another aspect of the present invention, the light emitting device comprises a groove formed in a wedge shape along the boundary surface by the pair of slant surfaces.

Also, according to another aspect of the present invention, the III-nitride semiconductor light emitting comprises a groove formed in a wedge shape along the boundary surface by the pair of slant surfaces, wherein the substrate comprises a broken surface below the substrate-side slant surface, and is a sapphire substrate.

Also, according to another aspect of the present invention, there is provided a method for manufacturing a III-nitride semiconductor light emitting device comprising: a substrate; a plurality of III-nitride semiconductor layers formed on the substrate, and provided with an active layer generating light by recombination of electrons and holes; and a boundary surface defined between the substrate and the plurality of III-nitride semiconductor layers, the method, comprising: a first step of exposing the boundary surface; and a second step of etching the substrate and the plurality of III-nitride semiconductor layers on both sides of the boundary surface to form a slant surface.

Also, according to another aspect of the present invention, the method comprises a third step of separating the substrate as an individual device.

Also, according to another aspect of the present invention, in the first step, the boundary surface is exposed by means of a laser scribing.

Also, according to another aspect of the present invention, in the second step, the slant surface is formed by means of a wet etching.

Also, according to another aspect of the present invention, the wet etching is carried out using a mixed solution of H₂SO₄ and H₃PO₄.

### ADVANTAGEOUS EFFECTS

According to a III-nitride semiconductor light emitting device and a method for manufacturing the same of the present invention, external quantum efficiency can be improved.

Also, according to a III-nitride semiconductor light emitting device and a method for manufacturing the same of the present invention, light can be easily extracted by forming a slant surface on a side surface thereof.

Also, according to a III-nitride semiconductor light emitting device and a method for manufacturing the same of the present invention, light can be easily extracted by forming a slant surface on a substrate thereof.

### DESCRIPTION OF DRAWINGS

FIG. 1 is a view illustrating one example of a conventional III-nitride semiconductor light emitting device.

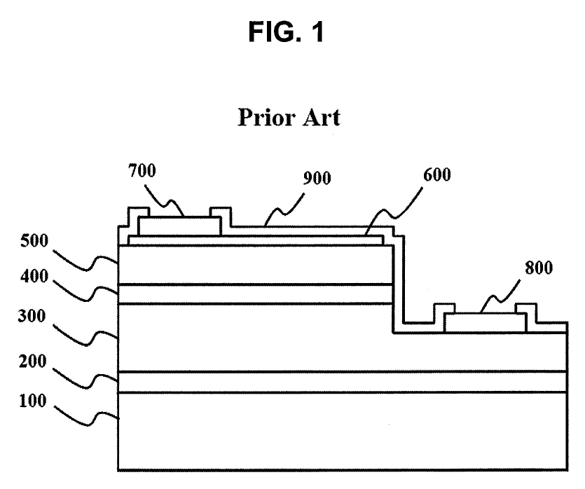

FIG. 2 is a view illustrating one example of a light reflection path in a semiconductor layer of a light emitting device disclosed in U.S. Pub. No. 2006-0192247.

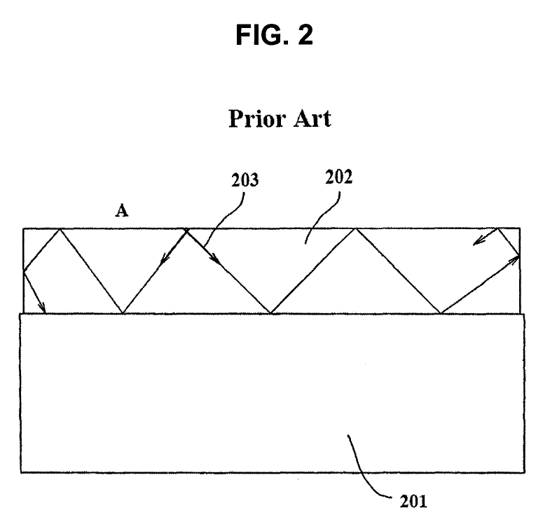

FIG. 3 is a view illustrating one example of a light emitting device disclosed in Japan Patent 2836687.

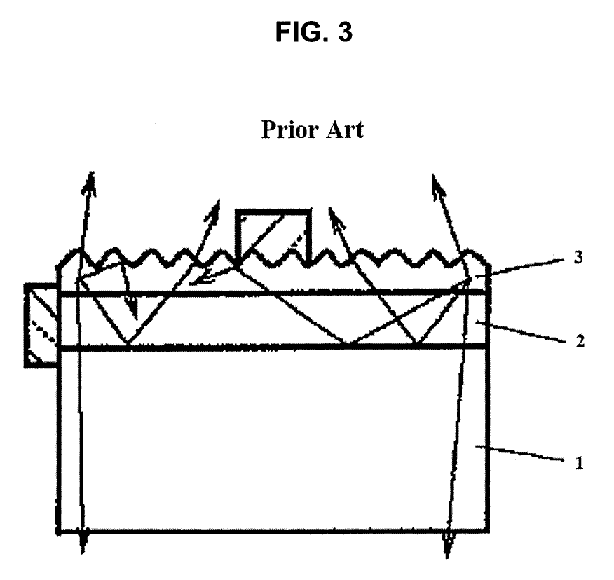

FIG. 4 is a view illustrating one example of a light emitting device disclosed in U.S. Pub. No. 2006-0192247.

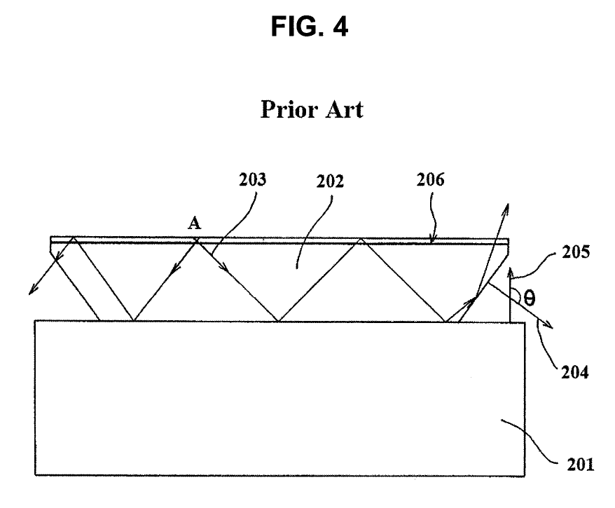

FIG. 5 is a view illustrating a III-nitride semiconductor light emitting device according to an embodiment of the present invention.

FIG. 6 is a photograph showing the III-nitride semiconductor light emitting device according to the embodiment of the present invention.

FIG. 7 is a view illustrating a light path in the III-nitride semiconductor light emitting device according to the present invention.

FIG. 8 is a graph showing external quantum efficiency of the III-nitride semiconductor light emitting device according to the present invention.

### MODE FOR INVENTION

Hereinafter, the present invention will be described in detail with reference to the accompanying drawings.

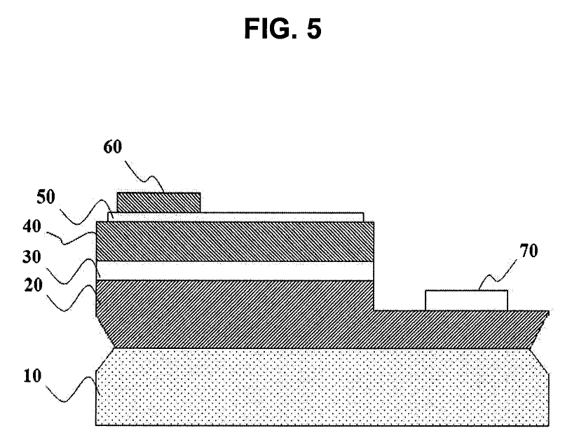

FIG. 5 is a view illustrating a III-nitride semiconductor light emitting device according to an embodiment of the present invention. The III-nitride semiconductor light emitting device includes a substrate 10, an n-type nitride semiconductor layer 20 epitaxially grown on the substrate 10, an active layer 30 epitaxially grown on the n-type nitride semiconductor layer 20, a p-type nitride semiconductor layer 40 epitaxially grown on the active layer 30, a p-side electrode 50 formed on the p-type nitride semiconductor layer 40, a p-side bonding pad 60 formed on the p-side electrode 50, and an n-side electrode 70 formed on the n-type nitride semiconductor layer 20 exposed by etching the p-type nitride semiconductor layer 40 and the active layer 30.

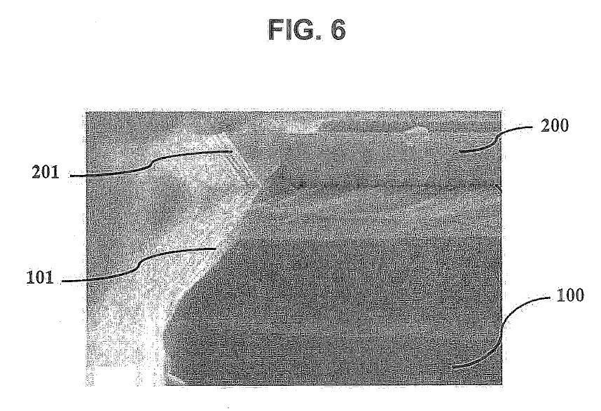

FIG. 6 is a photograph showing the III-nitride semiconductor light emitting device according to the embodiment of the present invention. The III-nitride semiconductor light emitting device includes a boundary surface 15, slant surfaces 11 and 21, and a broken surface 13. The boundary surface 15 is formed between the substrate 10 and the n-type nitride semiconductor layer 20. The slant surfaces 11 and 21 are formed from the boundary surface 15 on side surfaces of the substrate 10 and the n-type nitride semiconductor layer 20 in order to facilitate external emission of light generated in the active layer (30; see FIG. 5). Here, the substrate 10 is preferably formed of sapphire. The slant surfaces 11 and 21 forming the side surfaces of the substrate 10 and the n-type nitride semiconductor layer 20 are formed in a wedge shape as a whole to easily extract light.

The broken surface 13 is formed below the substrate-side slant surface 11. Formation of the broken surface 13 will be explained later.

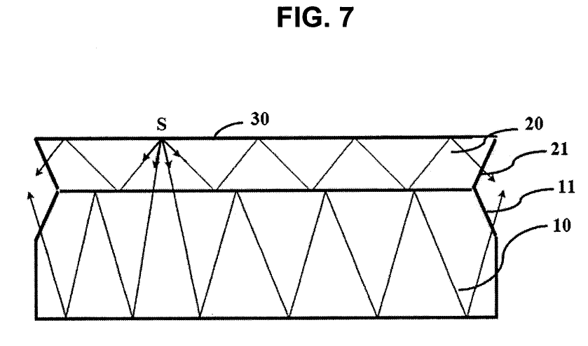

FIG. 7 is a view illustrating a light path in the III-nitride semiconductor light emitting device according to the present invention. Light generated in the active layer 30 and reflected in the substrate 10 and the n-type nitride semiconductor layer 20 is emitted to the outside of the light emitting device through the slant surfaces 11 and 21. As a result, the light emitting device improves external quantum efficiency.

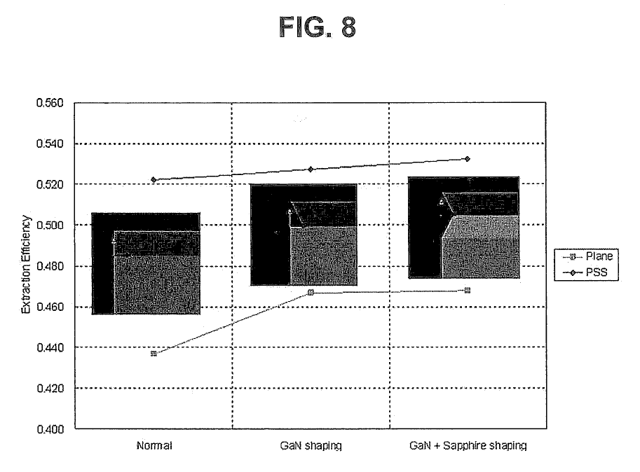

FIG. 8 is a graph showing light efficiency of the III-nitride semiconductor light emitting device according to the present invention, particularly, external quantum efficiency of a III-nitride semiconductor light emitting device (normal) including a substrate and an n-type nitride semiconductor layer with normal side surfaces, a III-nitride semiconductor light emitting device (GaN shaping) including a normal substrate and an n-type nitride semiconductor layer with a slant surface, and a III-nitride semiconductor light emitting device (GaN+Sapphire shaping) according to the present invention. As shown in FIG. 8, the III-nitride semiconductor light emitting device according to the present invention has the most excellent external quantum efficiency.

Hereinafter, a method for manufacturing the III-nitride semiconductor light emitting device according to the present invention will be described in detail with reference to FIG. 7.

The method for manufacturing the III-nitride semiconductor light emitting device according to the present invention includes a first step of exposing the boundary surface 15, a second step of etching the substrate 10 and the n-type nitride semiconductor layer 20 on both sides of the boundary surface 15 to form the slant surfaces 11 and 21, and a third step of separating the substrate 10 as an individual device. In this embodiment, the boundary surface 15 is exposed by means of a laser scribing. Preferably, an exposed depth of the substrate 10 ranges from 0.5 μm to 30 μm so that the light emitting device can be easily separated by a physical force. If the depth is below 0.5 μm, when the light emitting device is separated by a physical force, the surface and inside of the device may be cracked, or an electrical characteristic thereof may be affected. On the contrary, if the depth is over 30 μm, the device may be easily broken during the process to thereby reduce productivity. A diamond cutter can be used for the scribing, but a laser is advantageous in a process speed.

Meanwhile, the second step of forming the slant surfaces 11 and 21 is carried out by means of a wet etching. For example, an etching fluid is a mixed fluid of H₂SO₄ and H₃PO₄ at a mixed ratio of 3:1. Preferably, the etching fluid is used when it is heated over 150° C. If a temperature of the etching fluid is below 150° C., an etching rate of the side surfaces of the substrate 10 and the n-type nitride semiconductor layer 20 is lowered. For this reason, in this embodiment, when the light emitting device is etched, the temperature of the etching fluid ranges from 280° C. to 290° C., and an etching time is within 30 minutes. Here, the boundary surface 15 of the substrate 10 and the n-type nitride semiconductor layer 20 is actively etched because the boundary surface 15 is an unstable interface of different materials. In addition, debris generated by the laser scribing are removed during the wet etching, so that the light emitting device improves external quantum efficiency. Moreover, a buffered oxide etchant (BOE) can be used as the etching fluid.

In the third step, the substrate 10 is broken and separated into an individual device. Therefore, in the separated individual device, the broken surface 13 is formed below the substrate-side slant surface 11.

1. A III-nitride semiconductor light emitting device, comprising:
a substrate having a top surface, a bottom surface and a side peripheral surface, at least a portion of the side peripheral surface forming a slant surface;
a plurality of III-nitride semiconductor layers formed on the substrate, and provided with an active layer generating light by recombination of electrons and holes, at least a portion of the plurality of III-nitride semiconductor layers forming a slant surface on a side peripheral surface thereof; and
a boundary surface defined between the substrate and the plurality of III-nitride semiconductor layers,
wherein both said slant surface of the substrate and said slant surface of the at least a portion of the plurality of III-nitride semiconductor layers extend to said boundary surface to emit light generated in the active layer to the outside.

2. The III-nitride semiconductor light emitting device of claim 1, wherein the substrate comprises a broken surface below the slant surface of the substrate, the broken surface being formed during separation of one semiconductor light emitting device from another.

3. The III-nitride semiconductor light emitting device of claim 1, wherein the substrate is a sapphire substrate.

4. The III-nitride semiconductor light emitting device of claim 1, wherein said slant surface of the substrate and said slant surface of the at least a portion of the plurality of III-nitride semiconductor layers define a wedge-shaped groove along a peripheral edge of the boundary surface.

5. (canceled)

6. A method for manufacturing a III-nitride semiconductor light emitting device comprising a substrate; a plurality of III-nitride semiconductor layers formed on the substrate, and provided with an active layer generating light by recombination of electrons and holes; and a boundary surface defined between the substrate and the plurality of III-nitride semiconductor layers, the method comprising the steps of:
exposing the boundary surface; and
etching the substrate to form a slant surface on at least a portion of a side peripheral surface of the substrate and etching the plurality of III-nitride semiconductor layers to form a slant surface on a side peripheral surface of at least a portion of the plurality of III-nitride semiconductor layers.

7. The method of claim 6, comprising the step of separating the substrate as an individual device wherein a broken surface is formed during separation of the substrate below the slant surface of the substrate.

8. The method of claim 6, wherein, in the step of exposing, the boundary surface is exposed by means of a laser scribing.

9. The method of claim 6, wherein, in the step of etching, the slant surface is formed by means of a wet etching.

10. The method of claim 9, wherein the wet etching is carried out using a mixed solution of H₂SO₄ and H₃PO₄.

11. The method of claim 6, wherein an exposed depth of the substrate is in the range of 0.5μ to 30μ.

12. The method of claim 6, wherein both said slant surface of the substrate and said slant surface of the at least a portion of the plurality of III-nitride semiconductor layers extend to said boundary surface.

13. A III-nitride semiconductor light emitting device, comprising:
a substrate including a side peripheral surface, the side peripheral surface forming a tapered portion;
a plurality of III-nitride semiconductor layers formed above the substrate, and provided with an active layer generating light by recombination of electrons and holes, at least a portion of the plurality of III-nitride semiconductor layers forming a tapered portion on a side peripheral surface thereof; and
a boundary surface defined between the substrate and the plurality of III-nitride semiconductor layers,
wherein both said tapered portion of the substrate and said tapered portion of the at least a portion of the plurality of III-nitride semiconductor layers are tapered toward said boundary surface.

14. The III-nitride semiconductor light emitting device of claim 13 wherein the substrate comprises a broken surface below the tapered portion of the substrate, the broken surface being formed during separation of one semiconductor light emitting device from another.

15. The III-nitride semiconductor light emitting device of claim 13 wherein the substrate is a sapphire substrate.

16. The III-nitride semiconductor light emitting device of claim 13 wherein said tapered portion of the substrate and said tapered portion of the at least a portion of the plurality of III-nitride semiconductor layers define a wedge-shaped groove along a peripheral edge of the boundary surface.
